(19) United States
(12) Patent Application Publication
(10) Pub. No.: US 2022/0221491 A1
(43) Pub. Date: Jul. 14, 2022

(54) PROBE CARD DEVICE

(71) Applicant: teCat Technologies (Suzhou) Limited, Suzhou City (CN)

(72) Inventor: CHOON LEONG LOU, Suzhou City (CN)

(73) Assignee: teCat Technologies (Suzhou) Limited, Suzhou City (CN)

(21) Appl. No.: 17/364,841

(22) Filed: Jun. 30, 2021

(30) Foreign Application Priority Data
Jan. 8, 2021 (CN) 202120055746.8

(51) Int. Cl. G01R 1/073

(52) U.S. Cl. CPC G01R 1/07371

(57) ABSTRACT

A probe card device is provided. The probe card device includes a circuit substrate, an interposer, an adapter board and a probe assembly. The interposer is coupled to the circuit substrate, and the adapter board is coupled to the interposer. The probe assembly is coupled to the adapter board, and the probe assembly is electrically connected to the circuit substrate through the interposer and the adapter board. One terminal of each of the probes is electrically connected to the circuit substrate. Another terminal of each of the probes is in contact with a test object. The interposer, the adapter board and the test object have the same material properties.

### CROSS-REFERENCE TO RELATED PATENT APPLICATION

This application claims the benefit of priority to China Patent Application No. 202120055746.8, filed on Jan. 8, 2021 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a probe card device, and more particularly to a probe card device with a carrier plate having the same material properties as a test object.

### BACKGROUND OF THE DISCLOSURE

The present disclosure provides a probe card device for an electrical characteristics testing or an aging testing of semiconductor integrated circuits, which involves a probe testing of semiconductor integrated circuit wafers at different temperatures.

When testing the wafers with precision instruments such as probe card devices, effects of ambient conditions such as humidity, pressure and temperature, need to be considered. Particularly, effects of ambient conditions are important for high-density vertical probe card devices.

In the conventional probe card devices, a position of a probe needle may shift due to a thermal expansion of structural components under different temperature conditions (high temperature, low temperature and room temperature).

Therefore, how to overcome the above-mentioned inadequacy through improving the structural design has become one of the important issues to be solved in the field.

### SUMMARY OF THE DISCLOSURE

In response to the above-referenced technical inadequacies, the present disclosure provides a probe card device that includes a circuit substrate, an interposer, an adapter board and a probe assembly. The interposer is coupled to the circuit substrate. The adapter board is directly coupled to the interposer and is not in contact with the circuit substrate. The probe assembly is coupled to the adapter board, and is electrically connected to the circuit substrate through the interposer and the adapter board. One terminal of each of probes is electrically connected to the circuit substrate, and another terminal of each of the probes is in contact with a test object. The interposer, the adapter board and the test object have the same material properties.

In certain embodiments, the interposer and the adapter board are integrally formed.

In certain embodiments, the probe assembly includes a vertical probe.

In certain embodiments, the material property includes a hardness, a ductility, an electrical conductivity or a coefficient of thermal expansion.

In certain embodiments, the interposer and the adapter board each are made of silicon nitride, aluminum nitride, silicon carbide, zinc oxide, gallium nitride or gallium arsenide.

Therefore, one of the beneficial effects of the present disclosure is that, in the probe card device provided by the present disclosure, a carrier plate has the same thermal expansion effect as the test object, so as to improve an alignment precision of the probe to the test object by virtue of “the interposer, the adapter board and the test object having the same material properties”.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawing, in which:

FIG. 1 is a schematic view of a probe card device according to a first embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

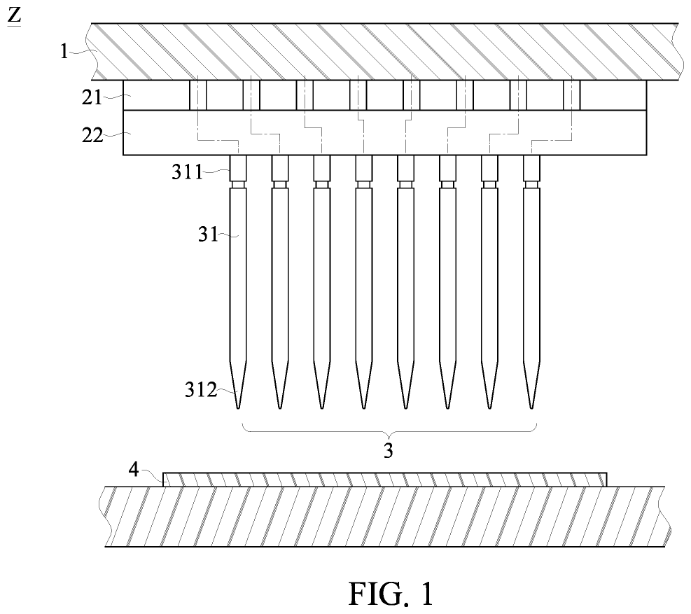

Referring to FIG. 1, a first embodiment of the present disclosure provides a probe card device Z that includes a circuit substrate 1, an interposer 21, an adapter board 22 and a probe assembly 3. The circuit substrate 1 is a printed circuit board. The interposer 21 is coupled to the circuit substrate 1. The adapter board 22 is a space transformer, and is coupled to the interposer 21. The adapter board 22 is used to transmit electrical signals and power signals between the circuit substrate 1 and the probe assembly 3. The probe assembly 3 is coupled to the adapter board 22, and is electrically connected to the circuit substrate 1 through the interposer 21 and the adapter board 22. One terminal 311 of each of probes 31 is electrically connected to the circuit substrate 1, and another terminal 312 of each of the probes 31 is in contact with a test object 4. The interposer 2 has the same material properties as the test object 4. The interposer 21, the adapter board 22 and the test object 4 have the same material properties. The material property includes, but not limited to, a hardness, a ductility, an electrical conductivity or a coefficient of thermal expansion.

Specifically speaking, the probe card device Z is a high-density vertical probe card device. Since the interposer 21 has the same material properties as the adapter board 22, the interposer 21 and the adapter board 22 can be integrally formed.

The interposer 21 and the adapter board 22 each are made of silicon nitride, aluminum nitride, silicon carbide, zinc oxide, gallium nitride or gallium arsenide. For example, if the test object 4 is a wafer to be tested and is made of a silicon nitride substrate, the interposer 21 and the adapter board 22 can be made of the same silicon nitride substrate as the wafer to be tested. Since a plurality of probes 31 of the probe assembly 3 are directly implanted on the adapter board 22, which has the same material properties as the wafer to be tested, the wafer to be tested has the same thermal expansion effect as the interposer 21 and the adapter board 22. Accordingly, a shift of a position to be tested on a surface of the wafer to be tested due to a thermal expansion is the same as a shift of the plurality of probes 31 due to the thermal expansion, thereby improving an alignment precision of the probe card device Z to the test object 4. However, the present disclosure in not limited to the example described above.

[Beneficial Effects of the Embodiment]

In conclusion, one of the beneficial effects of the present disclosure is that, in the probe card device provided by the present disclosure, the interposer 21 and the adapter board 22 have the same thermal expansion effect as the test object 4, so as to improve the alignment precision of the probe 31 to the test object 4 by virtue of “the interposer 21, the adapter board 22 and the test object 4 having the same material properties”.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A probe card device, comprising:
a circuit substrate;
an interposer coupled to the circuit substrate;
an adapter board directly coupled to the interposer and not in contact with the circuit board; and
a probe assembly including a plurality of probes, the probe assembly being coupled to the adapter board, the probe assembly being electrically connected to the circuit board through the interposer and the adapter board, one terminal of each of the probes being electrically connected to the circuit substrate, another terminal of each of the probes being in contact with a test object, wherein the interposer, the adapter board and the test object have the same material properties.

2. The probe card device according to claim 1, wherein the interposer and the adapter board are integrally formed.

3. The probe card device according to claim 1, wherein the probe assembly includes a vertical probe.

4. The probe card device according to claim 1, wherein the material property includes a hardness, a ductility, an electrical conductivity or a coefficient of thermal expansion.

5. The probe card device according to claim 1, wherein the interposer and the adapter board each are made of silicon nitride, aluminum nitride, silicon carbide, zinc oxide, gallium nitride or gallium arsenide.
